(19) United States
(12) Patent Application Publication
(10) Pub. No.: US 2024/0069447 A1
(43) Pub. Date: Feb. 29, 2024

(54) BUTTRESSED FIELD TARGET DESIGN FOR OPTICAL AND E-BEAM BASED METROLOGY TO ENABLE FIRST LAYER PRINT REGISTRATION MEASUREMENTS FOR FIELD SHAPE MATCHING AND RETICLE STITCHING IN HIGH NA LITHOGRAPHY

(71) Applicant: Intel Corporation, Santa Clara, CA (US)

(72) Inventors: Deepak SELVANATHAN, Portland, OR (US); William T. BLANTON, Cornelius, OR (US); Martin WEISS, Portland, OR (US)

(21) Appl. No.: 17/896,105

(22) Filed: Aug. 26, 2022

(51) Int. Cl. G03F 7/20; G03F 9/00

(52) U.S. Cl. CPC G03F 7/70633; G03F 9/7084; G03F 9/7088; G03F 7/2022

(57) ABSTRACT

An apparatus of manufacturing a semiconductor device is provided. The apparatus including a controller configured to: expose a first region of a photoresist layer with a light pattern, expose a second region of the photoresist layer with at least in part the same light pattern, wherein the second region and the first region overlap in an overlap region of the photoresist layer, and wherein light pattern is configured to form, in exposing the first region, a first portion of individual markings in the overlap region of the photoresist layer, and to form, in exposing the second region, a second portion of individual markings in the overlap region of the photoresist layer. By measuring the composite pattern formed in photoresist by overlapping the first exposure with the second exposure, the relative position of the two exposures can be determined and controlled.

### TECHNICAL FIELD

This disclosure generally relates to the field of manufacturing a semiconductor device.

### BACKGROUND

In integrated circuit (IC) manufacturing, elements of the IC to be created are reproduced in a pattern of transparent and opaque areas on the surface of a glass or plastic plate (also denoted as photomask or reticle). A photosensitive material (also denoted as photoresist) is deposited on a wafer, and the mask is positioned over the wafer and bright light, e.g. ultraviolet radiation, exposes the photoresist through the mask. Exposure to the light causes sections of the resist to either harden or soften, depending on the photoresist. After exposure, the wafer is further processed to develop the pattern of the mask in the wafer.

In the illumination of the photoresist, a step-and-repeat camera (stepper) projects the pattern of the mask one chip at a time. Thus, a wafer stage moves the wafer to illuminate the photoresist with the pattern of the mask subsequently for each of the ICs to be formed on the wafer. A step-and-scan system (scanners) images a smaller portion of the mask for an individual IC, e.g. sub-areas of individual ICs. Step-and-scan systems are widespread and are often simply referred to as steppers too.

The area of individual ICs on the photoresist may be denoted as IC estate. Each IC estate may include an active region (also denoted as image field or field) and a frame region adjacent to the active region. Subsequent process steps form the elements of the circuit in the active region. One frame region is arranged between active regions of adjacent ICs. Starting from a plain wafer in the manufacturing process, no markings or landmarks are available for aligning the IC estates on the wafer. The photoresist is denoted as first level in this manufacturing stage.

Markings are formed in the frame region of the first level photoresist to determine orientations of the IC estates relative to each other. The information about the orientations of active areas of adjacent ICs may be used in subsequent process of manufacturing. As an example, auto-alignment systems may use the markings in the frame region to reduce the setup time needed to image multiple ICs on the wafer.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects of the invention are described with reference to the following drawings, in which:

FIG. 1A illustrates an apparatus to manufacture a semiconductor device;

FIG. 1B illustrates flow diagram of a method for manufacturing a semiconductor device;

FIG. 2A to 2C illustrate patterned photoresist layers;

FIG. 2D illustrates an individual marking of a photoresist layer;

FIG. 3A to 3B show illustrations of a placement of buttressed field targets in a true/false scribe;

FIG. 3C shows a comparative example of markings;

FIG. 4 shows illustrations of buttressed portions of individual markings in the photoresist layer;

FIG. 5 shows illustrations of buttressed portions of individual optical markings in the photoresist layer;

FIG. 6 shows illustrations of buttressed portions of individual electron-beam markings in the photoresist layer;

FIG. 7 shows an SEM image of an electron-beam based buttressed marking of the photoresist layer; and

FIG. 8 shows illustrations of high NA lithography mask clustering of small field shape to the full field mask.

### DESCRIPTION

The following detailed description refers to the accompanying drawings that show, by way of illustration, specific details and aspects in which the invention may be practiced.

The term “as an example” is used herein to mean “serving as an example, instance, or illustration”. Any aspect or design described herein as “as an example” is not necessarily to be construed as preferred or advantageous over other aspects or designs.

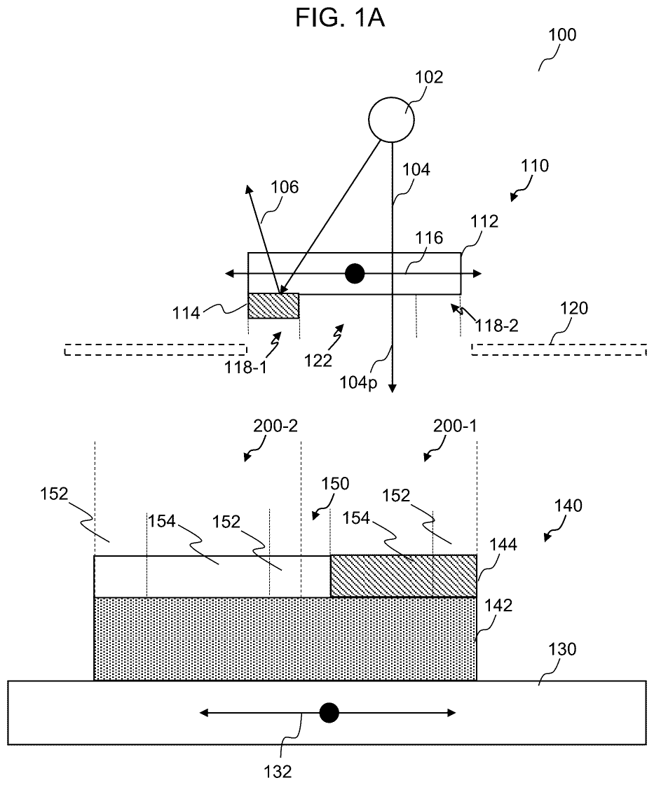

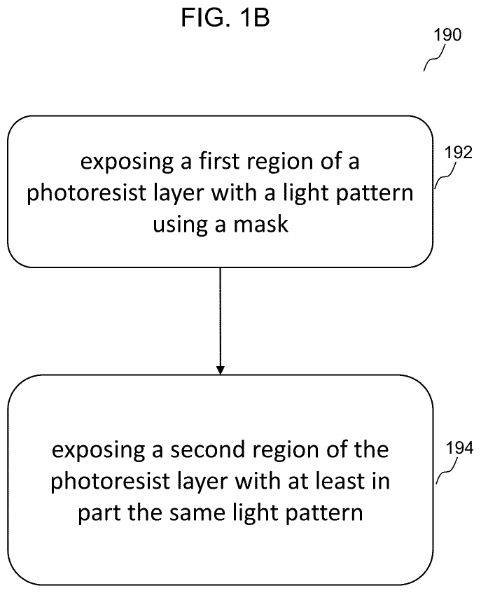

FIG. 1A illustrates an apparatus 100 for manufacturing a semiconductor device. The apparatus 100 may be or include a Stepper or Scanner in lithographic semiconductor device manufacturing.

The apparatus 100 includes a light source 102, a mask 110, and a target 140 on a target stage 130.

The light source 102 emits a radiation 104, e.g. an ultraviolet (UV) radiation or an electron beam for exposing a photoresist layer 144. Here, exposing of the photoresist layer 144 is meant to alter the properties of the photoresist layer 144 by the radiation. For the ease of explanation, UV radiation and electron beams are denoted as light, and the respective radiation source is denoted as light source. The light source 102 may include further components (not illustrated), e.g. one or more lens, one or more grating, one or more mirrors, and one or more optical filter.

The mask 110 may also be denoted as reticle 110. The mask 110 may be configured movable (in FIG. 1A illustrated by a first arrow 116), e.g. arranged on a mask stage. A stage may be an x-y-table for example. The mask 110 may be moved for adjusting the position regarding the target 140. Alternatively, or in addition, the mask 110 may be moved regarding a slit screen 120 (optional) to project only a portion of the mask at a time. The mask 110 may include a mask carrier 112 and a pattern 114. The carrier 112 may be transparent, e.g. a glass or quartz carrier. The pattern 114 may be opaque, e.g. reflective, for the light of the light source 102 (in FIG. 1A illustrated by arrow 106). The mask 110 may be of a transmission type (illustrated in FIG. 1A) or of a reflection type (not shown). The pattern 114 may be arranged on the side of the carrier 112 facing the light source 102, or on the opposite side (illustrated in FIG. 1A). Illustratively, the pattern 114 of the mask 110 may block light 106 from the light source 102 from reaching the target 140. This way, a light pattern 114p can expose the photoresist layer 144 of the target.

The pattern 114 of the mask may include a frame region 118-1, 118-2, and an active region. Components of the IC circuit may be formed by patterns in the active region 122 of the mask. The frame region 118-1, 118-2 may include a first section 118-1 on a first side, e.g. at a first edge, of the mask carrier 112, and a second section 118-2 on a first side, e.g. a second edge, of the mask carrier 112. The second side may be opposite side to the first side with the active region arranged in between. The first section 118-1 and the second section 118-2 may be arranged on the same surface side of the mask carrier 112 (illustrated in FIG. 1A). Alternatively, the first section 118-1 and the second section 118-2 may be formed on opposite surface sides of the mask carrier 112.

The target 140 may include a carrier 142 having a photoresist layer 144. The photoresist layer 144 may face the light source 102. The photoresist layer 144 may be a positive photoresist or a negative photoresist depending on the application. In other words, the photoresist layer 144 may become soluble or insoluble by the patterned light 104p exposure.

The carrier 142 may be or include a wafer, e.g. a silicon wafer, for example. The photoresist layer 144 may be a first layer or a higher layer of the target 140. In other words, the carrier 142 may be a plain wafer or a wafer having one or more layers on top of the wafer, e.g. metallization layers.

The target stage 130 may be configured movable (in FIG. 1 illustrated by a second arrow 132) to adjust the position of the target relative to the light source 102.

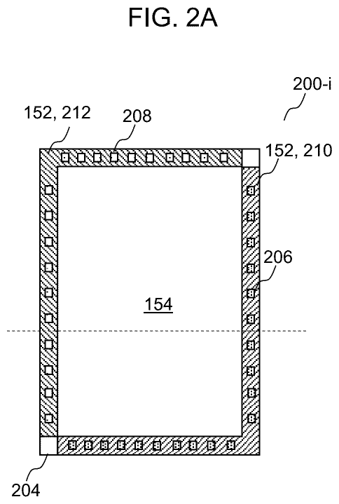

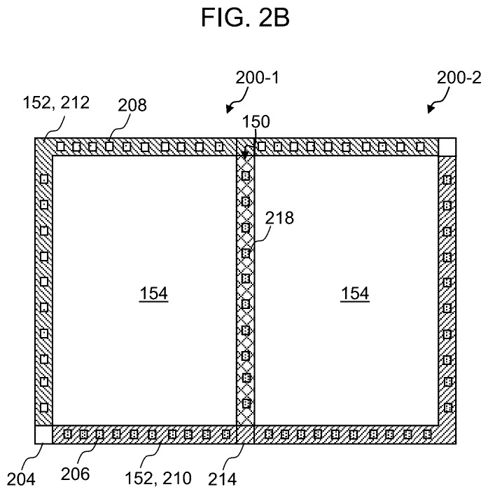

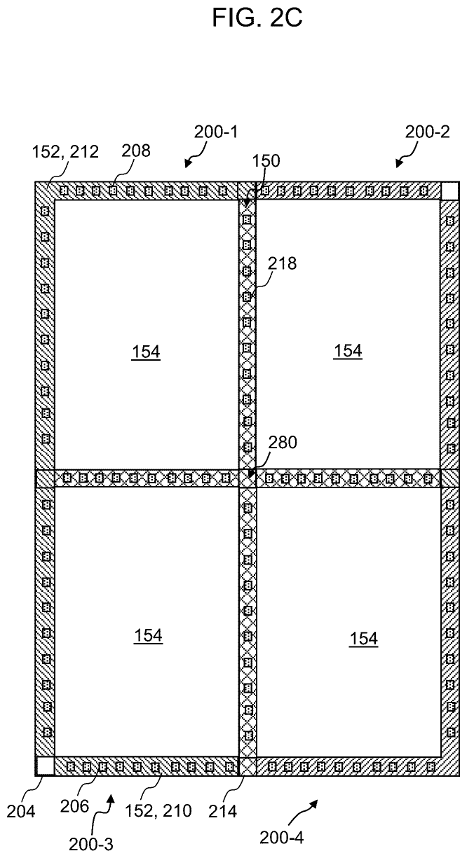

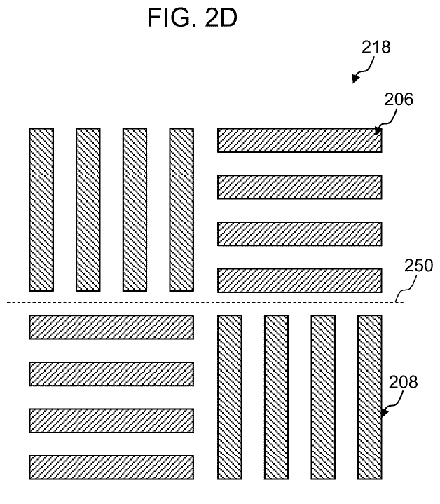

A plurality of integrated circuits (IC) is to be formed on the carrier 142. Each IC is formed in a field (in FIG. 1A illustrates a first field 200-1 for a first IC adjacent to a second field 200-2 for a second IC, see also FIG. 2A-2C). Each field 200-1, 200-2 includes a frame region 152 adjacent to an active region 154. Further process (not illustrated) form components and elements of the ICs in the active region 154 of a field 200-1, 200-2. The active region 154 of the photoresist layer 144 may correspond to the active region 122 of the mask 110, and the frame region 152 of the photoresist layer 144 may correspond to the frame region 118-1, 118-2 of the mask 112.

The frame region of adjacent fields 200-1, 200-2 may overlap in a portion of the photoresist layer 144 (also denoted as overlap region 150). The overlap region 150 separates active regions 154 of adjacent fields 200-1, 200-2. The overlap region 150 may be a buttressed region 150. The buttressed region 150 may be arranged at least a first time and a second time beneath the mask 110 and light source 102. However, in this case, at least a part of the buttressed region 150 is exposed only once to the light 104p of the light source 102.

The pattern 114 of the mask 110 includes markings in the frame region 118-1, 118-2 that form markings in the overlap region 150 of the photoresist layer 114, as illustrated in more detail in FIG. 2A to 2D.

An individual marking may be formed by at least a first portion and a second portion of the marking. In other words, the individual markings may be composite markings of at least a first portion and a second portion of the marking formed by exposing the first field 200-1 and the second field 200-2 subsequently with the patterned light 104p. The first portion of an individual marking may be formed in the buttressed region 150 while illuminating the first field 200-1 with patterned light 104p, and the second portion of the same markings may be formed in the buttressed region 150 while illuminating the second field 200-2 with patterned light 104p. In other words, individual markings may be formed in the buttressed region 150 by illuminating different fields 200-1, 200-2 of the photoresist layer 144. This way, the alignment of the first field 200-1 relative to the second field 200-2 can be determined by determining the alignment of the first portion of individual markings relative to the second portions of the marking. The alignment of the first and second portions of individual marks may be or include a spatial symmetry determined using a Fourier-Transformation (FT).

FIG. 1B illustrates a flow diagram of a method 190 for manufacturing a semiconductor device. The method 190 may include exposing 192 a first region of a photoresist layer with a light pattern using a mask, exposing 194 a second region of the photoresist layer with at least in part the same light pattern. The second region and the first region overlap in an overlap region of the photoresist layer. The light pattern is configured to form, in exposing the first region, a first portion of individual markings in the overlap region of the photoresist layer, and to form, in exposing the second region, a second portion of individual markings in the overlap region of the photoresist layer.

In other words, referring to FIG. 1A to FIG. 2D, the apparatus 100 may be configured for manufacturing a semiconductor device. The apparatus 100 may include a light source 102 configured to provide a light 104.

The apparatus 100 may include a mask 110 in the light path of the light 104. The mask 110 may include a pattern 114 configured to form a light pattern 104p from the provided light 104.

The apparatus 100 may include a movable carrier stage 130 configured to carrier a carrier 140. The carrier stage 130 may be an x-y table for example. The carrier 142 may include a photoresist layer 144. The carrier 142 may be or include a wafer. As an example, the carrier 142 may include one or more layers formed on a wafer. The photoresist layer 144 may be formed as the outer most layer, e.g. may have an exposed surface. The carrier stage 130 may move the carrier 142 to expose the second region 200-2 to the light pattern 104p after the first region 200-1 was exposed to the light pattern 104p.

The apparatus 100 may include a controller configured to: expose 192 a first region 200-1 of the photoresist layer 144 with the light pattern 104p, and expose 194 a second region 200-2 of the photoresist layer 144 with at least in part the same light pattern 104p. The second region 200-2 and the first region 200-1 may overlap in an overlap region 150 of the photoresist layer 144.

As an example, in case the first region 200-1 and the second region 200-2 form together an IC estate, the active region of the first region 200-1 may differ from the active region of the second region 200-2. However, the frame region of the first region 200-1 may be the same as the frame region in the second region 200-2. Here, the “same” is meant to form the individual markings from the first portion and the second portion of the markings.

As another example, in case each of the first region 200-1 and the second region 200-2 form an IC estate, the light pattern 104 p may be identical, e.g. the same, for each of the first region 200-1 and the second region 200-2. In particular, the frame region of the first region 200-1 may be the same as the frame region in the second region 200-2. Here, the “same” is meant to form the individual markings from the first portion and the second portion of the markings.

The mask 110 may be configured to form the light pattern 104p that forms, in exposing the first region 200-1, a first portion 206 of individual markings 218 in the overlap region 150 of the photoresist layer 144, and to form, in exposing the second region 200-2, a second portion 208 of individual markings 218 in the overlap region 150 of the photoresist layer 144 (see FIG. 2A to FIG. 2D).

The mask 110 may include an opaque pattern 114 that may have a frame region 118-1, 118-2 and an active region 122. The frame region may have a first section 118-1 and a second section 118-2. The active region 122 may spatially be arranged between the first section 118-1 and the second section 118-2. As an example, the mask 110 may have a similar appearance like the patterned photoresist layer illustrated in FIG. 2A.

The first section 118-1 may include a pattern corresponding to at least a first portion 206 of one or more markings 218 and the second section may include a pattern corresponding to at least a second portion 208 of the one or more markings 218. Each of the markings 218 may include at least one spatial symmetry between the first portion 206 and the second portion 208 (in FIG. 2D illustrated by the dashed lines 250). In other words, each marking 218 may include at least one spatial symmetry caused by the arrangement of the first portion 206 relative to the second portion 208.

The mask 110 may include a mask carrier 112. The opaque pattern 114 may be formed on or in the mask carrier 112. The first section 118-1 and the second section 118-2 may be arranged on the same surface on opposite sides of the mask carrier 112, as illustrated in FIG. 1A.

The opaque pattern 114 may be formed reflective for ultraviolet radiation. Alternatively, or in addition, the opaque pattern 114 may be formed reflective for an electron beam. The opaque pattern 114 may be configured for forming one or more components of a semiconductor device in the active region of the photoresist layer 144. The mask 110 may be configured to generate the light pattern 104p by reflecting light 106 from the light source 102.

The mask 110 further may include a movable mask stage (in FIG. 1A illustrated by the first arrow 116). The mask carrier 112 may be arranged on the movable mask stage (not illustrated). The mask stage may move the mask 110 to expose the second region 200-2 to the light pattern 104p after the first region 200-1 was exposed to the light pattern 104p.

The first region 200-1 may correspond to a first integrated circuit estate and the second region 200-2 may correspond to a second integrated circuit estate. In other words, the light pattern 104p may include an active region and a frame region, and the frame region in exposing the first region 200-1 and the frame region in exposing the second region 200-2 forms the overlap region 150. The active region may correspond to a first integrated circuit estate in the first region 200-1 and the active region may correspond to a second integrated circuit estate in the second region 200-2. The overlap region 150 may be arranged between the first integrated circuit estate and the second integrated circuit estate. The overlap region may include a scribe area between a first semiconductor device having the first integrated circuit estate and a second semiconductor device having the second integrated circuit estate.

Alternatively, or in addition, the first region 200-1 may correspond to a first portion of an integrated circuit estate and the second region 200-2 may correspond to a second portion of the same integrated circuit estate. In other words, the active region may correspond to a first portion of an integrated circuit estate in the first region 200-1 and the active region may correspond to a second portion of the same integrated circuit estate in the second region 200-2, and the overlap region 150 may be arranged between the first portion of the integrated circuit estate and the second portion of the integrated circuit estate.

FIG. 2A illustrates a top view of an individual region 200-i of a photoresist layer formed by patterned light 104p (see FIG. 1A). FIG. 2B illustrates a top view of a first region 200-1 adjacent to a second region 200-2 of a photoresist layer after subsequent exposure of the photoresist layer in the first region and the second region with patterned light 104p (see FIG. 1A). FIG. 2C illustrates a top view of a first region 200-1, a second region 200-2, a third region 200-3, and a fourth region 200-4 of a photoresist layer after subsequent exposure of the photoresist layer in the first region, the second region, third region, and the fourth region with patterned light 104p (see FIG. 1A). FIG. 2D illustrates a top view of an individual marking 218 including a first portion 206 formed in the photoresist layer while exposing a first region of the photoresist layer, and a second portion 208 formed in the photoresist layer while exposing a second region of the photoresist layer. Each of the portion 206, 208 may have a sub-structure, and illustrated structure of the marking 218 may be considered only as an illustrative example. The individual markings 218 may be configured to include at least one spatial symmetry when the first region 200-1 and the second region 200-2 are arranged in a predetermined manner to each other on the photoresist layer 144. The actual structure of an individual marking may depend on the used method to analyze the degree of symmetry of the markings, e.g. at least one of an optical method, an electron beam method, an x-ray method, a diffraction-based method, and a Moiré pattern.

As illustrated in FIG. 2A to 2C, a plurality of markings 218 may be arranged in the frame region 210, 212 along the active region 202 of a photoresist layer. A dense placement of the markings 218 may enable higher order modeling of the field grid shapes.

Each of the markings 218 may be formed by a first portion 206 and a second portion 208 that are formed in separate exposures of the photoresist layer. The frame region 152 of the regions 200-i (200-1, 200-2, 200-3, 200-4, . . . ) may differ in the part of the first portion 206 and the second portion 208 of the markings (in FIG. 2A to 2C illustrated as first sub-region 212 and second sub-region 210). Further, a portion of the frame region 204 may be free from exposure with light 104 when a exposing a region 200-i (also denoted as unexposed region 204 of a region 200-1). This way, an over-exposure of certain areas of the photoresist layer can be reduced or avoided. As an example, in FIG. 2C, the area 280 of the frame region of the photoresist layer shared by each of the first, second, third and fourth region 200-1, 200-2, 200-3, 200-4 would be exposed four times. However, this area 280 is only exposed two times due to the unexposed regions 204 of the second region 200-2 and third region 200-3.

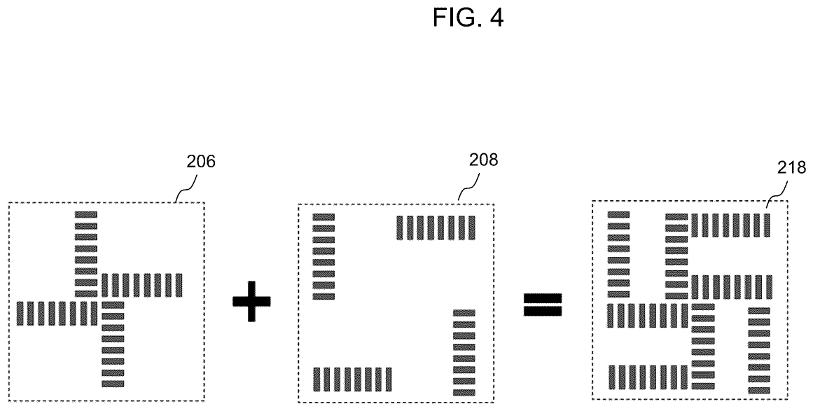

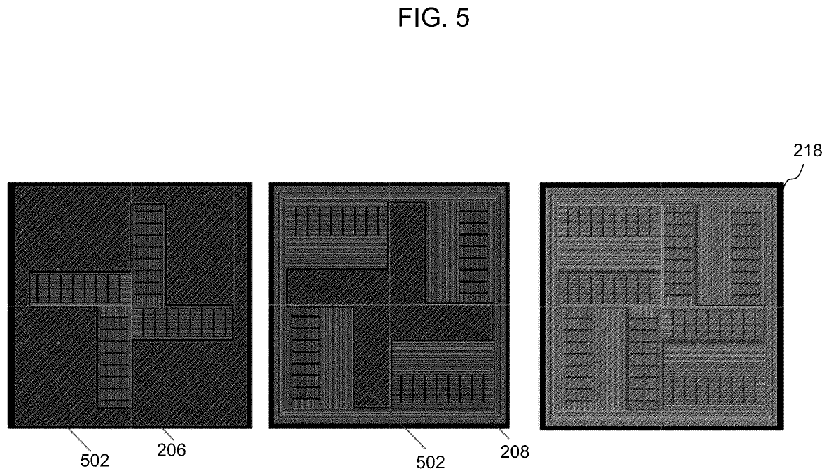

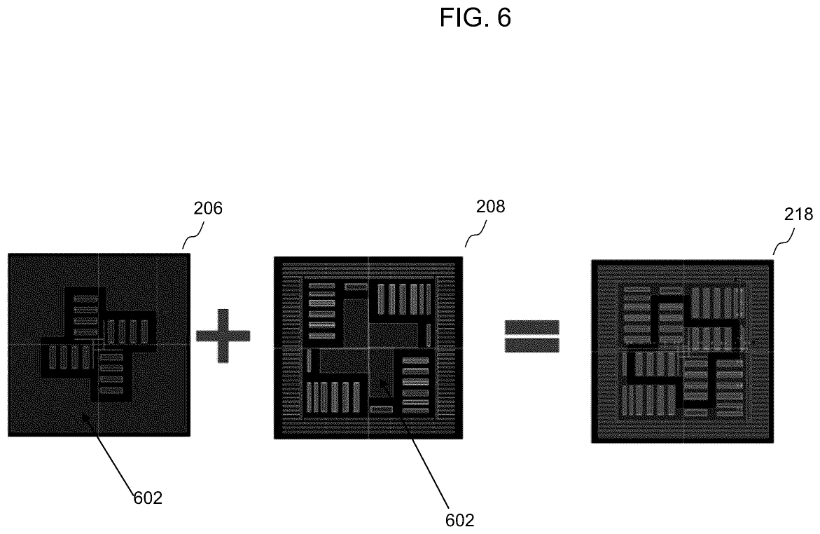

Further, in various embodiments, the plurality of markings 218 may include at least a first sub-section of markings, e.g. configured for an optical based analysis method (see also FIG. 4 and FIG. 5), and a second sub-section of markings different from the first section of markings, e.g. configured for an electron beam based analysis method (see also FIG. 6).

Further, with reference to FIGS. 1A and 2D, the controller of the apparatus 100 may be further configured to: determine the spatial symmetry 250 of at least one of the markings 218; and adjust at least one process based on the determined spatial symmetry. The process may be a process performed for the same semiconductor device, e.g. a subsequent structuring process. Alternatively, or in addition, the process may be a process performed for a subsequent semiconductor device, e.g. a carrier alignment process.

This way, a semiconductor device may be formed including at least a first region 200-1 and a second region 200-2 arranged on a common carrier, wherein a frame region may be arranged between the first region 200-1 and the second region 200-2; and one or more markings 218 may be arranged in the frame region, wherein each of the markings 218 may include a first portion 206 and a second portion 208 arranged in a spatial symmetry between the first portion and the second portion.

Illustratively, the semiconductor device may be formed by exposing a first region 200-1 of a photoresist layer 144 with a light pattern 104p using a mask 110, and exposing a second region 200-2 of the photoresist layer 144 with at least in part the same light pattern 104p. The second region 200-2 and the first region 200-1 overlap in an overlap region 150 of the photoresist layer 144. The light pattern 104p may be configured to form, in exposing the first region 200-1, a first portion 206 of individual markings 218 in the overlap region 150 of the photoresist layer 144, and to form, in exposing the second region 200-2, a second portion 208 of individual markings 218 in the overlap region 150 of the photoresist layer 144.

The carrier stage 130 may move the carrier 144 to expose the second region 200-2 to the light pattern 104p after the first region 200-1 was exposed to the light pattern 104p. Alternatively, or in addition, the movable mask stage may move the mask 110 to expose the second region 200-2 to the light pattern 104p after the first region 200-1 was exposed to the light pattern 104p.

Illustratively, the frame region of each IC estate may be divided in a first sub-region 212, e.g. true scribe, and a second sub-region 210, e.g. false scribe. As an example, a true scribe area of the mask may be transparent and a false scribe area of the mask may be opaque for an exposure of the photoresist, or vice versa.

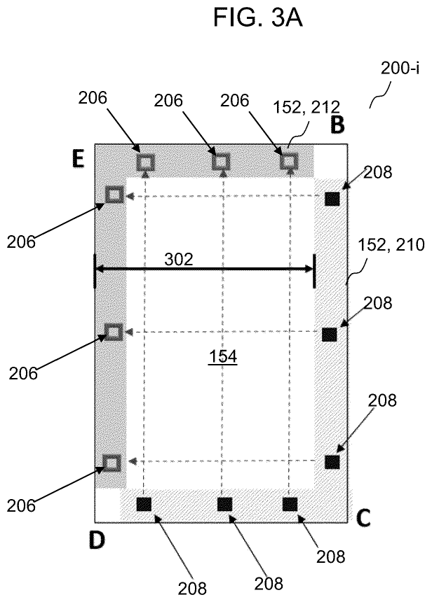

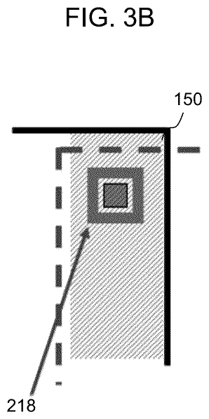

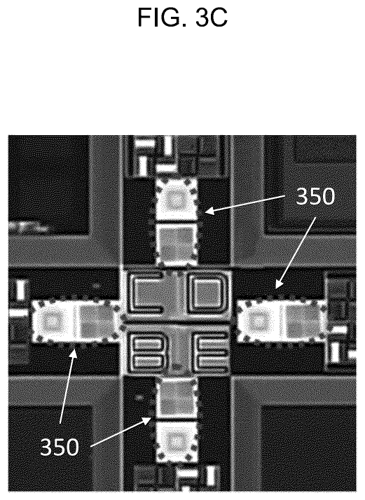

The first sub-region 212 of a frame region of a first IC estate may overlap with the second sub-region 210 of a frame region of an adjacent second IC estate. The overlap of a true scribe area and a false scribe area may be the buttressed region 150. FIG. 3A also illustrates the width 302 of a field of an IC estate.

Buttressed markings 218 (see FIG. 3B) may be used to control first layer print field shape for measurements using optical metrology with markings in the scribe lane of the semiconductor devices having the IC circuits, as shown in FIG. 3A.

Determining the alignment of the IC estates relative to each other, e.g. first layer registration measurements, may ensure field shape matching on wafers across various scanner tool platforms on downstream layers. These measurements provide feedback for a stable matching of the field shape printed across various scanners.

This way, field shape control on first layer prints is provided allowing improved downstream overlay control. Thus, overlay budgets in existing process technology can be improved. Also, the native size of the optical metrology based buttressed targets may affect the number of placements of the buttressed targets in the frame region, and thus orders of freedom may be improved that can be modeled from these measurements.

FIG. 3C illustrates a comparative example in which first and second portions of individual markings 350 are arranged adjacent to each other, and hence require a larger footprint and reduce the overlay budget compared to the buttressed markings as described before.

FIG. 4 shows illustrations of stepped buttressed markings 218 formed by overlay of a first portion 206 and a second portion 208 of the buttressed marking 218, e.g. the false scribe and true scribe features from adjacent fields.

FIG. 5 shows illustrations of a buttressed marking showing the blanking region and the measurement bars for optical bases analysis methods. Markings 218 composed by a first portion 206 and a second portion 208. A blank space 502 corresponding to the first portion 206 may be considered in the mask when exposing the photoresist layer to the second portion of the marking, and vice versa, to avoid or reduce an overexposure of the photoresist layer.

The buttressed markings 218 are illustrated for first layer print layers and may be composed of true scribe and false scribe targets. Inner measurement bars (e.g. including the first portion of the markings) may be formed in a false scribe and the outer measurement bars (e.g. including the second portion of the markings) may be formed in the true scribe of the frame region. Blanking space 502 may be used to cover the complementary portions of the marking in the true and false scribe markings to ensure that the inner measurement bars are not printed in the true scribe and the vice versa for the false scribe markings. This is illustrated in FIG. 5 where the true and false scribe portions of a marking, when stepped will create the buttressed markings 218. The optical marking 218 could be also box-in-box structures.

FIG. 6 shows illustrations of an electron beam based buttressed markings 218 composed by a first portion 206 and a second portion 208. A blank space 602 corresponding to the first portion 206 may be considered in the mask when exposing the photoresist layer to the second portion of the marking, and vice versa, to avoid or reduce an overexposure of the photoresist layer. Electron beam based buttressed markings may be smaller in size, e.g. 5×5 μm, compared to optical buttressed targets in size, e.g. ˜30×30 μm. Illustratively, optical buttressed markings field shape correction/control of first layer print. Higher order field correction models require multiple marking placements in the frame region. Thus, e-beam based buttressed markings may be placed in various locations, e.g. 15 locations along the external vertical scribe direction and about 10 locations along the external horizontal scribe direction.

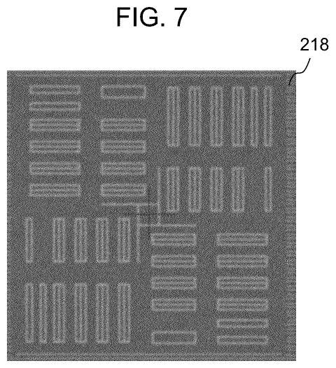

FIG. 7 shows a scanning electron microscope (SEM) image of an electron beam based buttressed marking.

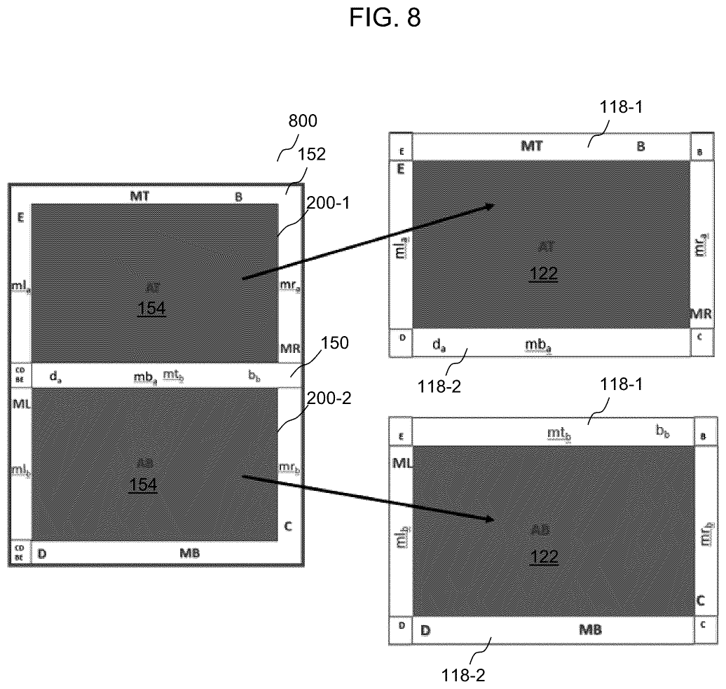

FIG. 8 illustrates a top view of an IC estate 800 formed by mask stitching, e.g. for high NA lithography. In high NA lithography, an individual IC estates 800 is formed by at least a first region 200-1 and a second region 200-2. High NA lithography may use r mask stitching of small field shapes with a full field mask shotmap. Thus, buttressed markings may be used in the overlap region 150 to enable mask stitching in high NA lithography applications.

As an example, in mask stitching (also denoted as reticle stitching, the mask frame may be split into a true scribe area (see FIG. 3A) which may include a first portion of the markings and a false scribe area that is mostly chrome to mask the true scribe, e.g. first portion, of the marking from being doubly exposed when the adjacent field is patterned on the scanner during the step/scan/expose process. The mask data for this marking may include two separate patterns: an inner layout, placed in the false scribe, and an outer layout, placed in the true scribe. The inner layout may include the first portions of the markings that are printed in the false scribe with the blanking mask pattern in the regions where the second portions of the markings are to be patterned. The outer layout may include the second portion of the markings that are to be printed in the true scribe and the complementary blanking region is used to mask the first portion of the markings, see also FIG. 3B.

Dummification patterns for one or more downstream layers of the semiconductor manufacturing method may be patterned in the first portion and or second portion of the markings (not illustrated).

When the scanner steps and prints the fields, true scribe patterns and false scribe patterns on the mask may be stepped and overlapped to form the final pattern of an IC estate in the photoresist layer on the wafer, as illustrated in FIG. 8.

High NA extreme ultraviolet (EUV) lithography has a limitation to the field size that can be patterned on the scanner. Typically, 2:1 clustering of the small field shapes is used in practice. This clustering of small field shapes may require the need for buttressed markings so that the multiple small field shapes can be matched to a (theoretical) full field mask and to each other as well. The placement of the markings 218 around the small field frames enables the registration control of the field shapes.

### EXAMPLES

The examples set forth herein are illustrative and not exhaustive.

Example 1 is a method of manufacturing a semiconductor device, the method including: exposing a first region of a photoresist layer with a light pattern using a mask, exposing a second region of the photoresist layer with at least in part the same light pattern, wherein the second region and the first region overlap in an overlap region of the photoresist layer, wherein the light pattern is configured to form, in exposing the first region, a first portion of individual markings in the overlap region of the photoresist layer, and to form, in exposing the second region, a second portion of individual markings in the overlap region of the photoresist layer.

In Example 2, the subject matter of Example 1 can optionally include that the photoresist layer is formed on a carrier.

In Example 3, the subject matter of Example 2 can optionally include that the carrier is a wafer.

In Example 4, the subject matter of Example 2 can optionally include that the carrier includes one or more layers formed on a wafer.

In Example 5, the subject matter of any one of Examples 1 to 4 can optionally include that the photoresist layer is formed on a carrier arranged on a movable stage, and wherein the stage moves the carrier to expose the second region to the light pattern after the first region was exposed to the light pattern.

In Example 6, the subject matter of any one of Examples 1 to 5 can optionally include that the mask is arranged on a movable stage, and wherein the stage moves the mask to expose the second region to the light pattern after the first region was exposed to the light pattern.

In Example 7, the subject matter of any one of Examples 1 to 6 can optionally include that the first region corresponds to a first integrated circuit estate and the second region corresponds to a second integrated circuit estate.

In Example 8, the subject matter of any one of Examples 1 to 7 can optionally further include forming one or more components of the semiconductor device in the first integrated circuit estate, and separating the first integrated circuit estate from the second integrated circuit estate.

In Example 9, the subject matter of any one of Examples 1 to 8 can optionally include that the light pattern includes an active region and a frame region, and wherein the frame region in exposing the first region and the frame region in exposing the second region forms the overlap region, wherein the active region corresponds to a first integrated circuit estate in the first region and the active region corresponds to a second integrated circuit estate in the second region, and wherein the overlap region is arranged between the first integrated circuit estate and the second integrated circuit estate.

In Example 10, the subject matter of any one of Examples 1 to 9 can optionally further include forming one or more components of the semiconductor device in the active regions of at least one of the first integrated circuit estate and the second integrated circuit estate, and separating the first integrated circuit estate from the second integrated circuit estate.

In Example 11, the subject matter of any one of Examples 1 to 6 can optionally include that the first region corresponds to a first portion of an integrated circuit estate and the second region corresponds to a second portion of the same integrated circuit estate.

In Example 12, the subject matter of Example 11 can optionally include that the light pattern includes an active region and a frame region, and wherein the frame region in exposing the first region and the frame region in exposing the second region forms the overlap region, wherein the active region corresponds to a first portion of an integrated circuit estate in the first region and the active region corresponds to a second portion of the same integrated circuit estate in the second region, and wherein the overlap region is arranged between the first portion of the integrated circuit estate and the second portion of the integrated circuit estate.

In Example 13, the subject matter of any one of Examples 1 to 12 can optionally include that the overlap region includes a scribe area of the semiconductor device.

In Example 14, the subject matter of any one of Examples 1 to 13 can optionally include that the mask generates the light pattern by partially transmitting light from the light source and/or reflecting light from a light source. In general, a mask can modulate the final optical intensity in the photoresist layer by reflection, absorption, and phase shifting.

In Example 15, the subject matter of any one of Examples 1 to 14 can optionally include a slit screen arranged between the mask and the photoresist layer, wherein the light pattern exposes the photoresist layer through the slit screen.

In Example 16, the subject matter of any one of Examples 1 to 15 can optionally include that the individual markings are configured to include at least one spatial symmetry when the first region and the second region are arranged in a predetermined manner to each other on the photoresist layer.

In Example 17, the subject matter of Example 16 can optionally further include determining the spatial symmetry of at least one of the markings; and adjusting at least one process based on the determined spatial symmetry.

In Example 18, the subject matter of Example 17 can optionally include that the process is a process performed for the same semiconductor device.

In Example 19, the subject matter of Example 17 can optionally include that the process is a process performed for a subsequent semiconductor device.

Example 20 is a semiconductor device including: at least a first region and a second region arranged on a common carrier, wherein a frame region is arranged between the first region and the second region; and one or more markings arranged in the frame region, wherein each of the markings includes a first portion and a second portion arranged in a spatial symmetry between the first portion and the second portion.

In Example 21, the subject matter of Example 20 can optionally include that the carrier is a wafer.

In Example 22, the subject matter of Example 20 can optionally include that the carrier includes one or more layers formed on a wafer.

In Example 23, the subject matter of any one of Examples 20 to 22 can optionally include that the first region corresponds to a first integrated circuit estate and the second region corresponds to a second integrated circuit estate.

In Example 24, the subject matter of any one of Examples 20 to 23 can optionally include that the frame region is a scribe area for separating the first integrated circuit estate from the second integrated circuit estate.

In Example 25, the subject matter of any one of Examples 20 to 24 can optionally include that the first region corresponds to a first portion of an integrated circuit estate and the second region corresponds to a second portion of the same integrated circuit estate.

Example 26 is a mask for a photolithographic method, the mask including: an opaque pattern having a frame region and an active region, the frame region having a first section and a second section, and the active region spatially arranged between the first section and the second section, wherein the first section includes at least a first portion of one or more markings and the second section includes at least a second portion of the one or more markings; and wherein each of the markings include at least one spatial symmetry between the first portion and the second portion.

In Example 27, the subject matter of Example 26 can optionally further include a carrier, wherein the opaque pattern is formed on or in the carrier.

In Example 28, the subject matter of Example 26 or 27 can optionally include that the opaque pattern is formed reflective for ultraviolet radiation.

In Example 29, the subject matter of any one of Examples 26 to 28 can optionally include that the opaque pattern is formed reflective for an electron beam.

In Example 30, the subject matter of any one of Examples 26 to 29 can optionally include that the first section and the second section are arranged on the same surface on opposite sides of the carrier.

In Example 31, the subject matter of any one of Examples 26 to 30 can optionally further include a movable stage, wherein the carrier is arranged on the movable stage.

In Example 32, the subject matter of any one of Examples 26 to 31 can optionally include that the opaque pattern is configured for forming one or more components of a semiconductor device in the active region.

Example 33 is a non-transitory computer readable medium having instructions stored that, when executed by a controller, cause the controller to: expose a first region of a photoresist layer with a light pattern using a mask, expose a second region of the photoresist layer with at least in part the same light pattern, wherein the second region and the first region overlap in an overlap region of the photoresist layer, wherein the light pattern is configured to form, in exposing the first region, a first portion of individual markings in the overlap region of the photoresist layer, and to form, in exposing the second region, a second portion of individual markings in the overlap region of the photoresist layer.

In Example 34, the subject matter of Example 33 can optionally include that the photoresist layer is formed on a carrier.

In Example 35, the subject matter of Example 34 can optionally include that the carrier is a wafer.

In Example 36, the subject matter of any one of Examples 33 to 35 can optionally include that the carrier includes one or more layers formed on a wafer.

In Example 37, the subject matter of any one of Examples 33 to 36 can optionally include that the photoresist layer is formed on a carrier arranged on a movable stage, and wherein the stage moves the carrier to expose the second region to the light pattern after the first region was exposed to the light pattern.

In Example 38, the subject matter of any one of Examples 33 to 37 can optionally include that the mask is arranged on a movable stage, and wherein the stage moves the mask to expose the second region to the light pattern after the first region was exposed to the light pattern.

In Example 39, the subject matter of any one of Examples 33 to 38 can optionally include that the first region corresponds to a first integrated circuit estate and the second region corresponds to a second integrated circuit estate.

In Example 40, the subject matter of Example 39 can optionally further include instructions configured to cause the controller to form one or more components of the semiconductor device in the first integrated circuit estate, and separate the first integrated circuit estate from the second integrated circuit estate.

In Example 41, the subject matter of any one of Examples 33 to 39 can optionally include that the light pattern includes an active region and a frame region, and wherein the frame region in exposing the first region and the frame region in exposing the second region forms the overlap region, wherein the active region corresponds to a first integrated circuit estate in the first region and the active region corresponds to a second integrated circuit estate in the second region, and wherein the overlap region is arranged between the first integrated circuit estate and the second integrated circuit estate.

In Example 42, the subject matter of any one of Examples 33 to 41 can optionally further include instructions configured to cause the controller to: form one or more components of the semiconductor device in the active regions of at least one of the first integrated circuit estate and the second integrated circuit estate, and separate the first integrated circuit estate from the second integrated circuit estate.

In Example 43, the subject matter of any one of Examples 33 to 42 can optionally include that the first region corresponds to a first portion of an integrated circuit estate and the second region corresponds to a second portion of the same integrated circuit estate.

In Example 44, the subject matter of any one of Examples 33 to 43 can optionally include that the light pattern includes an active region and a frame region, and wherein the frame region in exposing the first region and the frame region in exposing the second region forms the overlap region, wherein the active region corresponds to a first portion of an integrated circuit estate in the first region and the active region corresponds to a second portion of the same integrated circuit estate in the second region, and wherein the overlap region is arranged between the first portion of the integrated circuit estate and the second portion of the integrated circuit estate.

In Example 45, the subject matter of any one of Examples 33 to 44 can optionally include that the overlap region includes a scribe area of the semiconductor device.

In Example 46, the subject matter of any one of Examples 33 to 45 can optionally include that the mask generates the light pattern by partially transmitting light from the light source and/or reflecting light from a light source.

In Example 47, the subject matter of any one of Examples 33 to 46 can optionally further include a slit screen arranged between the mask and the photoresist layer, wherein the light pattern exposes the photoresist layer through the slit screen.

In Example 48, the subject matter of any one of Examples 33 to 47 can optionally include that the individual markings are configured to include at least one spatial symmetry when the first region and the second region are arranged in a predetermined manner to each other on the photoresist layer.

In Example 49, the subject matter of any one of Examples 33 to 48 can optionally further include instructions configured to cause the controller to: determine the spatial symmetry of at least one of the markings; and adjust at least one process based on the determined spatial symmetry.

In Example 50, the subject matter of Example 49 can optionally include that the process is a process performed for the same semiconductor device.

In Example 51, the subject matter of Example 49 can optionally include that the process is a process performed for a subsequent semiconductor device.

Example 52 is an apparatus of manufacturing a semiconductor device, the apparatus including: a light source configured to provide a light; a mask in the light path of the light, wherein the mask includes a pattern configured to form a light pattern from the provided light; a movable carrier stage configured to carrier a carrier, wherein the carrier includes a photoresist layer; and a controller configured to: expose a first region of the photoresist layer with the light pattern, expose a second region of the photoresist layer with at least in part the same light pattern, wherein the second region and the first region overlap in an overlap region of the photoresist layer, and wherein the mask is configured to form the light pattern that forms, in exposing the first region, a first portion of individual markings in the overlap region of the photoresist layer, and to form, in exposing the second region, a second portion of individual markings in the overlap region of the photoresist layer.

In Example 53, the subject matter of Example 52 can optionally include that the carrier is a wafer.

In Example 54, the subject matter of Example 52 can optionally include that the carrier includes one or more layers formed on a wafer.

In Example 55, the subject matter of any one of Examples 52 to 54 can optionally include that the carrier stage moves the carrier to expose the second region to the light pattern after the first region was exposed to the light pattern.

In Example 56, the subject matter of any one of Examples 52 to 55 can optionally include that the mask is arranged on a movable mask stage, and wherein the mask stage moves the mask to expose the second region to the light pattern after the first region was exposed to the light pattern.

In Example 57, the subject matter of any one of Examples 52 to 56 can optionally include that the first region corresponds to a first integrated circuit estate and the second region corresponds to a second integrated circuit estate.

In Example 58, the subject matter of any one of Examples 52 to 57 can optionally include that the light pattern includes an active region and a frame region, and wherein the frame region in exposing the first region and the frame region in exposing the second region forms the overlap region, wherein the active region corresponds to a first integrated circuit estate in the first region and the active region corresponds to a second integrated circuit estate in the second region, and wherein the overlap region is arranged between the first integrated circuit estate and the second integrated circuit estate.

In Example 59, the subject matter of any one of Examples 52 to 58 can optionally include that the first region corresponds to a first portion of an integrated circuit estate and the second region corresponds to a second portion of the same integrated circuit estate.

In Example 60, the subject matter of any one of Examples 52 to 59 can optionally include that the light pattern includes an active region and a frame region, and wherein the frame region in exposing the first region and the frame region in exposing the second region forms the overlap region, wherein the active region corresponds to a first portion of an integrated circuit estate in the first region and the active region corresponds to a second portion of the same integrated circuit estate in the second region, and wherein the overlap region is arranged between the first portion of the integrated circuit estate and the second portion of the integrated circuit estate.

In Example 61, the subject matter of any one of Examples 52 to 60 can optionally include that the overlap region includes a scribe area of the semiconductor device.

In Example 62, the subject matter of any one of Examples 52 to 57 can optionally include that the mask is configured to generate the light pattern by partially transmitting light from the light source and/or reflecting light from the light source.

In Example 63, the subject matter of any one of Examples 52 to 62 can optionally further include a slit screen arranged between the mask and the photoresist layer, wherein the light pattern exposes the photoresist layer through the slit screen.

In Example 64, the subject matter of any one of Examples 52 to 63 can optionally include that the individual markings are configured to include at least one spatial symmetry when the first region and the second region are arranged in a predetermined manner to each other on the photoresist layer.

In Example 65, the subject matter of any one of Examples 52 to 64 can optionally include that the controller is further configured to: determine the spatial symmetry of at least one of the markings; and adjust at least one process based on the determined spatial symmetry.

In Example 66, the subject matter of Example 65 can optionally include that the process is a process performed for the same semiconductor device.

In Example 67, the subject matter of Example 65 can optionally include that the process is a process performed for a subsequent semiconductor device.

Example 68 is a manufacturing means for manufacturing of a semiconductor means, including: a light pattern generator for exposing a first region of a photoresist structure with a light pattern using a masking means, and exposing a second region of the photoresist structure with at least in part the same light pattern, wherein the second region and the first region overlap in an overlap region of the photoresist structure, wherein the light pattern is configured to form, in exposing the first region, a first portion of individual markings in the overlap region of the photoresist structure, and to form, in exposing the second region, a second portion of individual markings in the overlap region of the photoresist structure.

In Example 69, the subject matter of Example 68 can optionally include that the photoresist structure is formed on a carrier means.

In Example 70, the subject matter of Example 69 can optionally include that the carrier means is a wafer.

In Example 71, the subject matter of Example 69 can optionally include that the carrier means includes one or more layers formed on a wafer.

In Example 72, the subject matter of any one of Examples 68 to 71 can optionally include that the photoresist structure is formed on a carrier means arranged on a movable mounting means, and wherein the mounting means moves the carrier means to expose the second region to the light pattern after the first region was exposed to the light pattern.

In Example 73, the subject matter of any one of Examples 68 to 72 can optionally include that the masking means is arranged on a movable mounting means, and wherein the mounting means moves the masking means to expose the second region to the light pattern after the first region was exposed to the light pattern.

In Example 74, the subject matter of any one of Examples 68 to 73 can optionally include that the first region corresponds to a first integrated circuit estate and the second region corresponds to a second integrated circuit estate.

In Example 75, the subject matter of any one of Examples 68 to 74 can optionally include that the light pattern includes an active region and a frame region, and wherein the frame region in exposing the first region and the frame region in exposing the second region forms the overlap region, wherein the active region corresponds to a first integrated circuit estate in the first region and the active region corresponds to a second integrated circuit estate in the second region, and wherein the overlap region is arranged between the first integrated circuit estate and the second integrated circuit estate.

In Example 76, the subject matter of any one of Examples 68 to 75 can optionally include that the first region corresponds to a first portion of an integrated circuit estate and the second region corresponds to a second portion of the same integrated circuit estate.

In Example 77, the subject matter of any one of Examples 68 to 73 can optionally include that the light pattern includes an active region and a frame region, and wherein the frame region in exposing the first region and the frame region in exposing the second region forms the overlap region, wherein the active region corresponds to a first portion of an integrated circuit estate in the first region and the active region corresponds to a second portion of the same integrated circuit estate in the second region, and wherein the overlap region is arranged between the first portion of the integrated circuit estate and the second portion of the integrated circuit estate.

In Example 78, the subject matter of any one of Examples 68 to 77 can optionally include that the overlap region includes a scribe area of the semiconductor means.

In Example 79, the subject matter of any one of Examples 68 to 78 can optionally include that the masking means generates the light pattern by partially transmitting light from the light source and/or reflecting light from a light emitting means.

In Example 80, the subject matter of any one of Examples 68 to 64 can further optionally include a screening means arranged between the masking means and the photoresist structure, wherein the light pattern exposes the photoresist structure through an opening means of the screening means.

In Example 81, the subject matter of any one of Examples 68 to 80 can optionally include that the individual markings are configured to include at least one spatial symmetry when the first region and the second region are arranged in a predetermined manner to each other on the photoresist structure.

In Example 82, the subject matter of any one of Examples 68 to 81 can optionally further include a controlling means for determining the spatial symmetry of at least one of the markings; and adjusting at least one process based on the determined spatial symmetry.

In Example 83, the subject matter of Example 82 can optionally include that the process is a process performed for the same semiconductor means.

In Example 84, the subject matter of Examples 82 can optionally include that the process is a process performed for a subsequent semiconductor means.

In Example 85, the subject matter of any one of Examples 1 to 84 can optionally include that the frame region of the patterned light, e.g. the frame region of the mask, includes at least one of a dummification pattern for at least one downstream process, and an unexposed area, e.g. an opaque area in the mask. The opaque area may allow to reduce or avoid an overexposure of photoresist layer.

While the invention has been particularly shown and described with reference to specific aspects, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. An apparatus for manufacturing a semiconductor device, the apparatus comprising:
a light source configured to provide a light;
a mask in the light path of the light, wherein the mask comprises a pattern configured to form a light pattern from the provided light;
a movable carrier stage configured to carrier a carrier, wherein the carrier comprises a photoresist layer; and
a controller configured to:
expose a first region of the photoresist layer with the light pattern,
expose a second region of the photoresist layer with at least in part the same light pattern, wherein the second region and the first region overlap in an overlap region of the photoresist layer, and
wherein the mask is configured to form the light pattern that forms, in exposing the first region, a first portion of individual markings in the overlap region of the photoresist layer, and to form, in exposing the second region, a second portion of individual markings in the overlap region of the photoresist layer.

2. The apparatus of claim 1,
wherein the mask is configured to generate the light pattern in the photoresist layer by reflection, absorption, and/or phase shifting.

3. The apparatus of claim 1, further comprising:
a slit screen arranged between the mask and the photoresist layer, wherein the light pattern exposes the photoresist layer through the slit screen.

4. The apparatus of claim 1, further comprising:
wherein the individual markings are configured to comprise at least one spatial symmetry when the first region and the second region are arranged in a predetermined manner to each other on the photoresist layer.

5. The apparatus of claim 1, the controller further configured to:
determine the spatial symmetry of at least one of the markings; and
adjust at least one process based on the determined spatial symmetry.

6. The apparatus of claim 5,
wherein the process is a process performed for the same semiconductor device.

7. The apparatus of claim 5,
wherein the process is a process performed for a subsequent semiconductor device.

8. A non-transitory computer readable medium having instructions stored thereon that, when executed by a controller, cause the controller to:
expose a first region of a photoresist layer with a light pattern using a mask,
expose a second region of the photoresist layer with at least in part the same light pattern, wherein the second region and the first region overlap in an overlap region of the photoresist layer,
wherein the light pattern is configured to form, in exposing the first region, a first portion of individual markings in the overlap region of the photoresist layer, and to form, in exposing the second region, a second portion of individual markings in the overlap region of the photoresist layer.

9. The computer readable medium of claim 8,
wherein the first region corresponds to a first integrated circuit estate and the second region corresponds to a second integrated circuit estate.

10. The computer readable medium of claim 9, wherein the instructions are further configured to cause the controller to form one or more components of the semiconductor device in the first integrated circuit estate, and separate the first integrated circuit estate from the second integrated circuit estate.

11. The computer readable medium of claim 8,
wherein the light pattern comprises an active region and a frame region, and wherein the frame region in exposing the first region and the frame region in exposing the second region forms the overlap region, wherein the active region corresponds to a first integrated circuit estate in the first region and the active region corresponds to a second integrated circuit estate in the second region, and wherein the overlap region is arranged between the first integrated circuit estate and the second integrated circuit estate.

12. The computer readable medium of claim 11, wherein the instructions are further configured to cause the controller to form one or more components of the semiconductor device in the active regions of at least one of the first integrated circuit estate and the second integrated circuit estate, and separate the first integrated circuit estate from the second integrated circuit estate.

13. The computer readable medium of claim 8,
wherein the first region corresponds to a first portion of an integrated circuit estate and the second region corresponds to a second portion of the same integrated circuit estate.

14. The computer readable medium of claim 13,
wherein the light pattern comprises an active region and a frame region, and wherein the frame region in exposing the first region and the frame region in exposing the second region forms the overlap region, wherein the active region corresponds to a first portion of an integrated circuit estate in the first region and the active region corresponds to a second portion of the same integrated circuit estate in the second region, and wherein the overlap region is arranged between the first portion of the integrated circuit estate and the second portion of the integrated circuit estate.

15. The computer readable medium of claim 8,
wherein the overlap region comprises a scribe area of the semiconductor device.

16. The computer readable medium of claim 8, further comprising:
wherein the individual markings are configured to comprise at least one spatial symmetry when the first region and the second region are arranged in a predetermined manner to each other on the photoresist layer.

17. The computer readable medium of claim 8, wherein the instructions are further configured to cause the controller to:
determine the spatial symmetry of at least one of the markings; and
adjust at least one process based on the determined spatial symmetry,
wherein the process is at least one of a process performed for the same semiconductor device and a process performed for a subsequent semiconductor device.

18. A semiconductor device comprising:
at least a first region and a second region arranged on a common carrier, wherein a frame region is arranged between the first region and the second region; and
one or more markings arranged in the frame region, wherein each of the markings comprises a first portion and a second portion arranged in a spatial symmetry between the first portion and the second portion.

19. The semiconductor device of claim 18,
wherein the first region corresponds to a first integrated circuit estate, and the second region corresponds to a second integrated circuit estate.

20. The semiconductor device of claim 18, wherein the frame region is a scribe area for separating the first integrated circuit estate from the second integrated circuit estate.

21. The semiconductor device of claim 18,
wherein the first region corresponds to a first portion of an integrated circuit estate, and the second region corresponds to a second portion of the same integrated circuit estate.

22. A mask for a photolithographic method, the mask comprising:
an opaque pattern having a frame region and an active region,
the frame region having a first section and a second section, and
the active region spatially arranged between the first section and the second section,
wherein the first section comprises at least a first portion of one or more markings, and the second section comprises at least a second portion of the one or more markings; and
wherein each of the markings comprises at least one spatial symmetry between the first portion and the second portion.

23. The mask of claim 22, further comprising a carrier, wherein the opaque pattern is formed on or in the carrier.

24. The mask of claim 22, wherein the first section and the second section are arranged on the same surface on opposite sides of the carrier.

25. The mask of claim 22, wherein the frame region comprises at least one of a dummification pattern for at least one downstream process, and an opaque area.
